(19) United States
(12) Patent Application Publication
(10) Pub. No.: US 2021/0223695 A1
(43) Pub. Date: Jul. 22, 2021

(54) DEVELOPMENT METHOD AND TREATMENT METHOD FOR PATTERNING METAL LAYER

(71) Applicant: WUHAN CHINA STAR OPTOELECTRONICS TECHNOLOGY CO., LTD, Wuhan, Hubei (CN)

(72) Inventor: Tianhua YI, Wuhan, Hubei (CN)

(21) Appl. No.: 16/099,198

(22) PCT Filed: Aug. 2, 2018
(86) PCT No.: PCT/CN2018/098298

§ 371 Date: Nov. 6, 2018

(30) Foreign Application Priority Data
Apr. 19, 2018 (CN) 201810352995.6

(51) Int. Cl. G03F 7/16; G03F 7/20

(52) U.S. Cl. CPC G03F 7/161; G03F 7/2051

(57) ABSTRACT

The invention provides a development method, including steps of providing a substrate, a first photoresist layer being after an exposure treatment disposed on the substrate, the first photoresist layer having an exposed area and an unexposed area; uniformly coating a developer on the first photoresist layer to form a first developer layer; applying a first development; applying a second development; and removing a remaining developer on the substrate after the second development is finished.

### FIELD OF INVENTION

The present invention relates to fields of liquid crystal display, and in particular to development methods and treatment methods for patterning a metal layer.

### BACKGROUND OF INVENTION

In conventional art, since an exposed area and an unexposed area of a photoresist layer have different solubilities in the developer during development, this results in a certain amount of the developer being wasted, and cannot effectively avoid uneven development due to pattern design.

Therefore, the conventional art has drawbacks and urgently need to be improved.

### TECHNICAL PROBLEM

An object of embodiments of the present invention is to provide a development method and treatment method for patterning a metal layer, which have the beneficial effects that improves the utilization ratio of the developer and optimizes the development uniformity.

### TECHNICAL SOLUTION

An embodiment of the present invention provides a development method, including steps of:

providing a substrate, a first photoresist layer being after an exposure treatment disposed on the substrate, the first photoresist layer having an exposed area and an unexposed area;

uniformly coating a developer on the first photoresist layer to form a first developer layer;

applying a first development: the first developer layer partially reacted with the first photoresist layer to accomplish the first development, and forming a second photoresist layer on the substrate, forming a photoresist/developer turbid layer on the second photoresist layer, and forming a second developer layer on the photoresist/developer turbid layer;

applying a second development: scraping the second developer layer and mixing the exposed area of the photoresist/developer turbid layer and the unexposed area of the photoresist/developer turbid layer, and the mixed photoresist/developer turbid layer continued to react with the second photoresist layer for the second development; and

removing a remaining developer on the substrate after the second development is finished,

wherein the second developer layer is scraped using a scraping strip; and the substrate is under a moving state during the development.

The development method according to the present invention, wherein after the second developer layer is scraped using the scraping strip during the second development, shaking the substrate to further enhance a degree of mixing of the photoresist/developer turbid layer on the exposed area and the unexposed area.

The development method according to the present invention, wherein a metal layer is disposed on the substrate, and the first photoresist layer is disposed on the metal layer.

The development method according to the present invention, wherein a thickness of the first photoresist layer is 1.5 μm.

Another embodiment of the present invention provides a development method, including steps of:

providing a substrate, a first photoresist layer being after an exposure treatment disposed on the substrate, the first photoresist layer having an exposed area and an unexposed area;

uniformly coating a developer on the first photoresist layer to form a first developer layer;

applying a first development: the first developer layer partially reacted with the first photoresist layer to accomplish the first development, and forming a second photoresist layer on the substrate, forming a photoresist/developer turbid layer on the second photoresist layer, and forming a second developer layer on the photoresist/developer turbid layer;

applying a second development: scraping the second developer layer and mixing the exposed area of the photoresist/developer turbid layer and the unexposed area of the photoresist/developer turbid layer, and the mixed photoresist/developer turbid layer continued to react with the second photoresist layer for a second development; and

removing a remaining developer on the substrate after the second development is finished.

The development method according to the present invention, wherein the second developer layer is scraped using a scraping strip.

The development method according to the present invention, wherein after the second developer layer is scraped using a scraping strip during the second development, shaking the substrate to further enhance a degree of mixing of the photoresist/developer turbid layer on the exposed area and the unexposed area.

The development method according to the present invention, wherein a metal layer is disposed on the substrate, and the first photoresist layer is disposed on the metal layer.

The development method according to the present invention, wherein a thickness of the first photoresist layer is 1.5 μm.

The development method according to the present invention, wherein the substrate is under a moving state during the development

A treatment method for patterning a metal layer, including steps of:

providing a substrate, a metal deposition layer disposed on the substrate;

providing a first photoresist layer on the metal deposition layer;

exposing the first photoresist layer to form an exposed area and an unexposed area, the exposed area forming a target pattern;

uniformly coating a developer on the first photoresist layer to form a first developer layer;

applying a first development: the first developer layer partially reacted with the first photoresist layer to accomplish the first development, and forming a second photoresist layer on the substrate, forming a photoresist/developer turbid layer on the second photoresist layer, and forming a second developer layer on the photoresist/developer turbid layer;

applying a second development: scraping the second developer layer and mixing the exposed area of the photoresist/developer turbid layer and the unexposed area of the photoresist/developer turbid layer, and the mixed photoresist/developer turbid layer continued to react with the second photoresist layer for a second development;

removing a remaining developer on the substrate after the second development is finished; and

etching to remove the metal deposition layer uncovered by the second photoresist layer after the development is finished.

The treatment method for patterning the metal layer according the present invention, wherein the second developer layer is scraped using a scraping strip.

The treatment method for patterning the metal layer according the present invention, after the second developer layer is scraped using a scraping strip during the second development, shaking the substrate to further enhance a degree of mixing of the photoresist/developer turbid layer on the exposed area and the unexposed area.

The treatment method for patterning the metal layer according the present invention, a thickness of the first photoresist layer is 1.5 μm.

The treatment method for patterning the metal layer according the present invention, the substrate is under a moving state during the development.

### BENEFICIAL EFFECT

From the above-mentioned, the present invention is through providing a substrate, a first photoresist layer being after an exposure treatment disposed on the substrate, the first photoresist layer having an exposed area and an unexposed area; uniformly coating a developer on the first photoresist layer to form a first developer layer; applying a first development: the first developer layer partially reacted with the first photoresist layer to accomplish the first development, and forming a second photoresist layer on the substrate, forming a photoresist/developer turbid layer on the second photoresist layer, and forming a second developer layer on the photoresist/developer turbid layer; applying a second development: scraping the second developer layer and mixing the exposed area of the photoresist/developer turbid layer and the unexposed area of the photoresist/developer turbid layer, and the mixed photoresist/developer turbid layer continued to react with the second photoresist layer for the second development; and removing a remaining developer on the substrate after the second development is finished. The development of the substrate is is finished, the development operation of substrate has the beneficial effects that improves the utilization of the developer and optimizes the development uniformity.

### DESCRIPTION OF DRAWINGS

To more clearly illustrates the technical solutions in the embodiments of the present invention, the drawings used in the description of the embodiments will be briefly described below. It is apparent that the drawings accompanying with the following description are only some embodiments of the present invention. Other drawings can also be obtained from those skilled in the art based on these drawings without paying any creative effort.

FIG. 1 is a schematic flow chart of a development method in some embodiments of the present invention.

FIG. 2 is a schematic structural drawing of a first photoresist layer in some embodiments of the present invention.

FIGS. 3-5 are detailed schematic flow chart of a development method in some embodiments of the present invention.

FIG. 6 is a schematic flow chart of a treatment method for patterning a metal layer in some embodiments of the present invention.

### DETAILED DESCRIPTION OF PREFERRED EMBODIMENTS

The embodiments of the present invention are described in detail below, and the examples of the implementation are illustrated in the drawings, and the same or similar reference numerals indicate the same or similar elements or elements having the same or similar functions. The embodiments described below with reference to the drawings are intended to be illustrative of the present invention and cannot be understood as limitations of the present invention.

In the description of the present invention, it is to be understood that the terms “center”, “longitudinal”, “transverse”, “length”, “width”, “thickness”, “upper”, “lower”, “front”, “back”, “left”, “right”, “vertical”, “horizontal”, “top”, “bottom”, “inner”, “outer”, “clockwise”, “counterclockwise”, etc., indicated orientation or positional relationship are based on the orientation or positional relationship shown in the drawings, and are merely for the convenience of describing the present invention and simplifying the description, instead of indicating or implying that the device or component referred to must have a particular orientation, constructed and operated in a particular orientation. Therefore, it cannot be constructed as a limitation of the present invention. Moreover, the terms “first” and “second” are only used for descriptive purposes and are not to be construed as indicating or implying a relative importance or implicitly indicating the number of technical features indicated. Thus, features defined “first” or “second” may include one or more features either explicitly or implicitly. In the description of the present invention, the term “a plurality of ” may be two or more than two, unless otherwise specifically defined.

In the description of the present invention, it should be noted that the terms “mount”, “connect to”, and “connection” should be understood broadly, for example, it can be a fixed connection, a removeable connection, or connected in one piece; it can be a mechanical connection, it can also be electrically connected or can be communicated with each other; it can be directly connected, it can also be indirectly connected through an intermediary medium. It can be the internal communication of two elements or the interaction of two elements. For those of ordinary skill in the art, the specific meaning of the above terms of the present invention can be understood on a case-by-case basis.

In the present invention, unless otherwise expressly stated and defined, a first feature “above” or “under” a second feature may include that the first feature directly contacts with the second feature, and may also include that the first feature does not directly contact with the second feature. Moreover, the first feature “on”, “above” and “over” the second feature includes the first feature right above and oblique upper the second feature, or merely indicating that a level of the first feature is higher than a level of the second feature. The first feature “below”, “under” and “ beneath” the second feature includes the first feature right below and oblique below the second feature, or merely indicating that a level of first feature is less than a level of the second feature.

The following disclosure provides many different embodiments or examples for implementing different structures of the present invention. In order to simplify the disclosure of the present invention, the components and arrangements of the specific examples are described below. Certainly, they are merely examples and are not intended to limit the invention. In addition, the present invention may be repeated with reference numerals and/or reference letters in the different examples, which are for the purpose of simplicity and clarity, and do not indicate the relationship between the various embodiments and/or arrangements discussed. Moreover, the present invention provides examples of various specific processes and materials, but one of ordinary skill in the art will recognize that other processes and/or the use of other materials can be used.

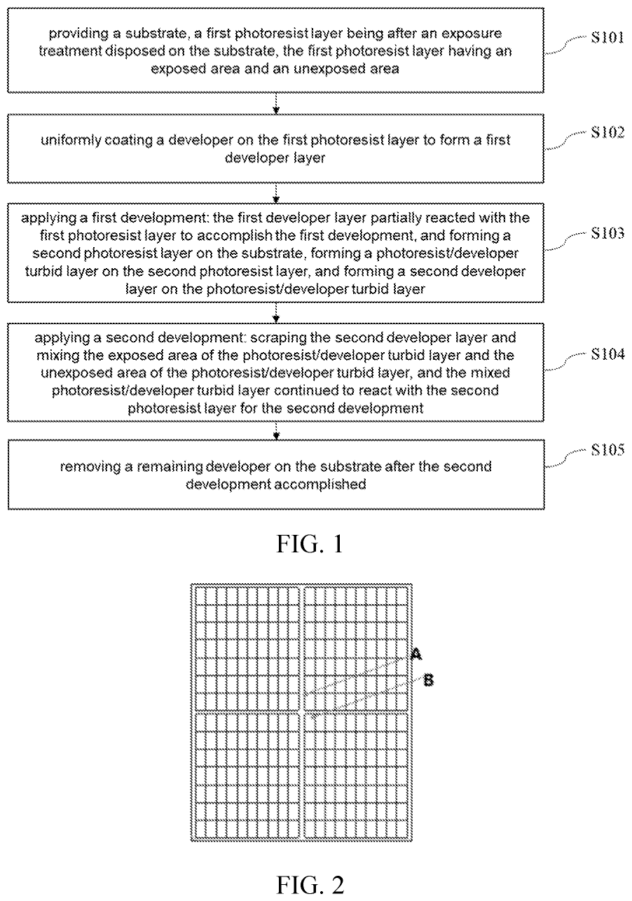

Please refer to FIG. 1. FIG. 1 is a flowchart of a development method in some embodiments of the present invention, the development method including the following steps:

STEP S101: providing a substrate, a first photoresist layer being after an exposure treatment disposed on the substrate, the first photoresist layer having an exposed area and an unexposed area.

STEP S102: uniformly coating a developer on the first photoresist layer to form a first developer layer.

STEP S103: applying a first development: the first developer layer partially reacted with the first photoresist layer to accomplish the first development, and forming a second photoresist layer on the substrate, forming a photoresist/developer turbid layer on the second photoresist layer, and forming a second developer layer on the photoresist/developer turbid layer.

STEP S104: applying a second development: scraping the second developer layer and mixing the exposed area of the photoresist/developer turbid layer and the unexposed area of the photoresist/developer turbid layer, and the mixed photoresist/developer turbid layer continued to react with the second photoresist layer for the second development.

STEP S105: removing a remaining developer on the substrate after the second development is finished.

The development method according to present invention, wherein the second developer layer is scraped using a scraping strip.

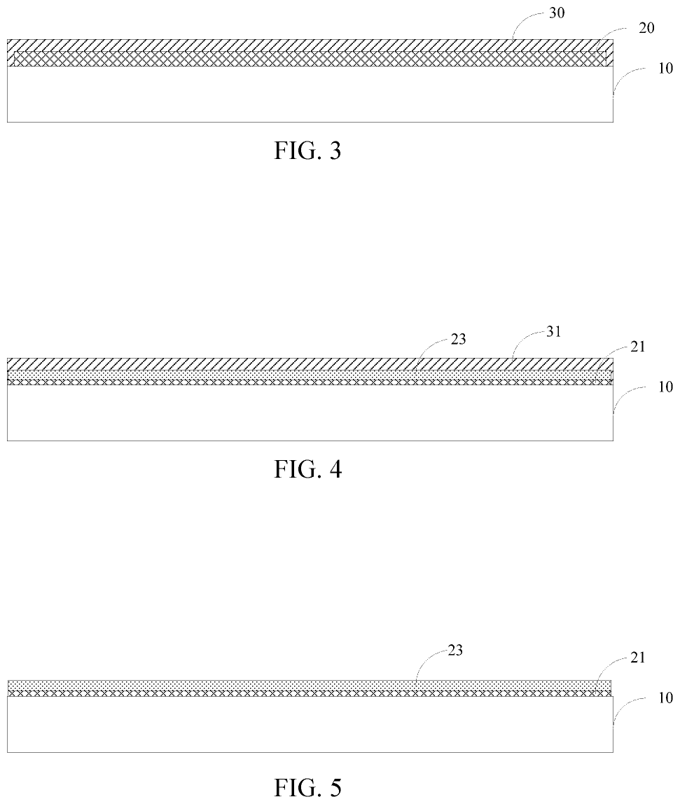

Each of the steps of the development method are described in detail below with reference to FIGS. 2-5.

In the step S101, the substrate 10 may be a glass substrate, a metal layer is formed on the glass substrate, and the first photoresist layer 20 is disposed on the metal layer. The first photoresist layer 20 is subjected to an exposure process to form an exposed area A and an unexposed area B. A thickness of the first photoresist layer 20 is 1.5 μm. In this step S102, the developer is uniformly coated on the first photoresist layer 20 to form the first developer layer 20 by moving the substrate 10. The substrate 10 is in a conveying state during the development.

In this step S103, the developer continuously dissolves the photoresist in the first photoresist layer 10. Thus, a second photoresist layer 21 is formed on the substrate 10, a photoresist/developer turbid layer 23 is formed on the second photoresist layer 21, and a second developer layer 31 is formed on the photoresist/developer mixture layer 23 finally. Wherein, after the first development is finished, since the photoresist in the non-exposed area B dissolves more, the photoresist/developer mixture layer in the non-exposed area B has been deactivated, that is, the dissolving of the photoresist has been stopped. While the photoresist in the exposed area A dissolves less, it can continue to dissolve the photoresist.

In the step S104, during the second development, the second developer layer 31 is scraped off using a scraping strip, and during the scraping process, the scraping strip disturbs the photoresist/developer mixture layer in the exposed area and the unexposed area, such that the mixtures of the photoresist/developer mixture layer in the exposed area and the unexposed area are mixed, resulting in concentration of the photoresist of the photoresist/developer mixture layer in the unexposed area deceased, thereby breaking the deactivation, the photoresist/developer mixture layer on the unexposed area continues to react with the second photoresist layer 21, the second development is finished. After the second developer layer is scraped using the scraping strip during the second development, shaking the substrate to further enhance mixing of the photoresist/developer turbid layer on the exposed area and the unexposed area.

In this step S105, the remaining developer can be removed using an air knife or a liquid jet.

From above mentioned, the present invention is implemented by providing a substrate, a first photoresist layer being after an exposure treatment disposed on the substrate, the first photoresist layer having an exposed area and an unexposed area; uniformly coating a developer on the first photoresist layer to form a first developer layer; applying a first development: the first developer layer partially reacted with the first photoresist layer to accomplish the first development, and forming a second photoresist layer on the substrate forming a photoresist/developer turbid layer on the second photoresist layer, and forming a second developer layer on the photoresist/developer turbid layer; applying a second development: scraping the second developer layer, and mixing the exposed area of the photoresist/developer turbid layer and the unexposed area of the photoresist/developer turbid layer, and the mixed photoresist/developer turbid layer continued to react with the second photoresist layer for the second development; removing a remaining developer on the substrate after the second development is finished. The development operation of the substrate is finished, which has beneficial effects of improving utilization rate of the developer and optimizing development uniformity.

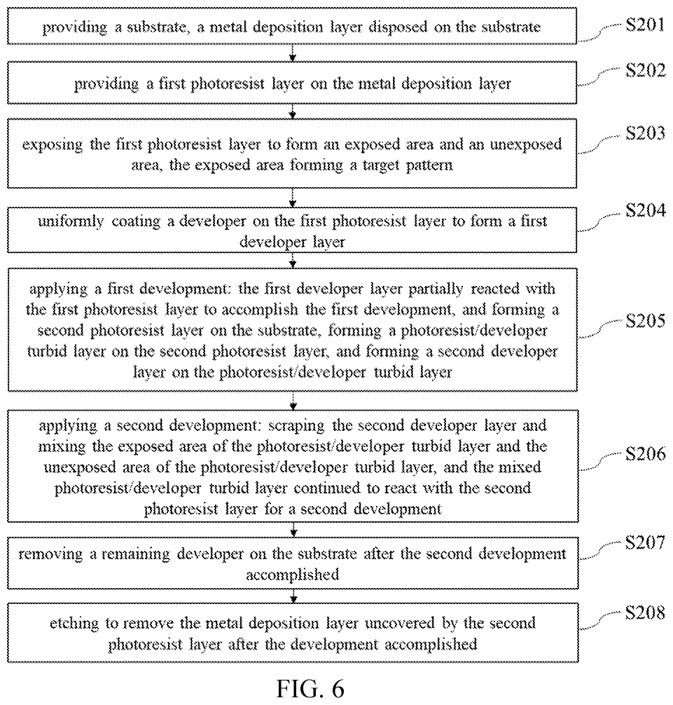

Please refer to FIG. 6. FIG. 6 is the treatment method for patterning the metal layer in some embodiments of the present invention, the treatment method for patterning the metal layer can be used in the manufacturing of an array substrate of liquid crystal display panels, for example, for manufacturing a light-shielding metal layer, thin film transistors, a pixel electrode layer, or a common electrode layer of an array substrate.

Wherein the treatment method for patterning the metal layer comprises the following steps:

Step S201, providing a substrate, a metal deposition layer disposed on the substrate;

Step S202, providing a first photoresist layer on the metal deposition layer;

Step S203, exposing the first photoresist layer to form an exposed area and an unexposed area, the exposed area forming a target pattern;

Step S204, uniformly coating a developer on the first photoresist layer to form a first developer layer;

Step S205, applying a first development: the first developer layer partially reacted with the first photoresist layer to accomplish the first development, and forming a second photoresist layer on the substrate, forming a photoresist/developer turbid layer on the second photoresist layer, and forming a second developer layer on the photoresist/developer turbid layer;

Step S206, applying a second development: scraping the second developer layer and mixing the exposed area of the photoresist/developer turbid layer and the unexposed area of the photoresist/developer turbid layer, and the mixed photoresist/developer turbid layer continued to react with the second photoresist layer for a second development;

Step S207, removing a remaining developer on the substrate after the second development is finished;

Step S208, etching to remove the metal deposition layer uncovered by the second photoresist layer after the development is finished.

Steps S204 to S207 are the same as steps S102 to S105 of the above embodiment, and therefore are not described again.

In the step S208, the etching process is similar to that in the prior art, so it will not be described in detail.

The development method and the treatment method for patterning the metal layer provided by the embodiments of the present invention are described hereabove in detail. The principles and embodiments of the present invention are described herein using specific examples. The description of the above embodiments is only for helping to understand the present invention. At the same time, for those skilled in the art, according to the idea of the present invention, there will has any changes in the specific implementation and application scope. In summary, the content of this specification should not be construed as limiting the invention.

What is claimed is:

1. A development method, comprising steps of:
providing a substrate, a first photoresist layer, after an exposure treatment, disposed on the substrate; the first photoresist layer having an exposed area and an unexposed area;
uniformly coating developer on the first photoresist layer to form a first developer layer;
applying a first development: the first developer layer partially reacting with the first photoresist layer to accomplish the first development, and forming a second photoresist layer on the substrate, forming a photoresist/developer turbid layer on the second photoresist layer, and forming a second developer layer on the photoresist/developer turbid layer;
applying a second development: scraping the second developer layer and mixing an exposed area of the photoresist/developer turbid layer and an unexposed area of the photoresist/developer turbid layer; the mixed photoresist/developer turbid layer continuing to react with the second photoresist layer for the second development; and
removing remaining developer on the substrate after the second development is finished,
wherein the second developer layer is scraped using a scraping strip; and
the substrate is under a moving state during a development.

2. The development method according to claim 1, wherein after the second developer layer is scraped using the scraping strip during the second development, shaking the substrate to further enhance a degree of mixing of the photoresist/developer turbid layer on the exposed area and the unexposed area.

3. The development method according to claim 1, wherein a metal layer is disposed on the substrate, and the first photoresist layer is disposed on the metal layer.

4. The development method according to claim 1, wherein a thickness of the first photoresist layer is 1.5 μm.

5. A development method, comprising steps of:
providing a substrate, a first photoresist layer being after an exposure treatment disposed on the substrate, the first photoresist layer having an exposed area and an unexposed area;
uniformly coating a developer on the first photoresist layer to form a first developer layer;
applying a first development: the first developer layer partially reacted with the first photoresist layer to accomplish the first development, and forming a second photoresist layer on the substrate, forming a photoresist/developer turbid layer on the second photoresist layer, and forming a second developer layer on the photoresist/developer turbid layer;
applying a second development: scraping the second developer layer and mixing the exposed area of the photoresist/developer turbid layer and the unexposed area of the photoresist/developer turbid layer, and the mixed photoresist/developer turbid layer continued to react with the second photoresist layer for a second development; and
removing a remaining developer on the substrate after the second development is finished.

6. The development method according to claim 5, wherein the second developer layer is scraped using a scraping strip.

7. The development method according to claim 6, wherein after the second developer layer is scraped using a scraping strip during the second development, shaking the substrate to further enhance a degree of mixing of the photoresist/developer turbid layer on the exposed area and the unexposed area.

8. The development method according to claim 5, wherein a metal layer is disposed on the substrate, and the first photoresist layer is disposed on the metal layer.

9. The development method according to claim 5, wherein a thickness of the first photoresist layer is 1.5 μm.

10. The development method according to claim 5, wherein the substrate is under a moving state during the development

11. A treatment method for patterning a metal layer, comprising steps of:
providing a substrate, a metal deposition layer disposed on the substrate;
providing a first photoresist layer on the metal deposition layer;
exposing the first photoresist layer to form an exposed area and an unexposed area, the exposed area forming a target pattern;
uniformly coating a developer on the first photoresist layer to form a first developer layer;
applying a first development: the first developer layer partially reacted with the first photoresist layer to accomplish the first development, and forming a second photoresist layer on the substrate, forming a photoresist/developer turbid layer on the second photoresist layer, and forming a second developer layer on the photoresist/developer turbid layer;
applying a second development: scraping the second developer layer and mixing the exposed area of the photoresist/developer turbid layer and the unexposed area of the photoresist/developer turbid layer, and the mixed photoresist/developer turbid layer continued to react with the second photoresist layer for a second development;
removing a remaining developer on the substrate after the second development is finished; and
etching to remove the metal deposition layer uncovered by the second photoresist layer after the development is finished.

12. The treatment method for patterning the metal layer according to claim 11, wherein the second developer layer is scraped using a scraping strip.

13. The treatment method for patterning the metal layer according to claim 12, wherein after the second developer layer is scraped using a scraping strip during the second development, shaking the substrate to further enhance a degree of mixing of the photoresist/developer turbid layer on the exposed area and the unexposed area.

14. The treatment method for patterning the metal layer according to claim 11, wherein a thickness of the first photoresist layer is 1.5 μm.

15. The treatment method for patterning the metal layer according to claim 11, wherein the substrate is under a moving state during the development.
